(19) United States
(12) Patent Application Publication
(10) Pub. No.: US 2026/0305140 A1
(43) Pub. Date: Oct. 1, 2026

(54) DISPLAY DEVICE

(71) Applicant: LG Display Co., Ltd., Seoul (KR)

(72) Inventor: HwaYoul Lee, Gimpo-si (KR)

(21) Appl. No.: 19/430,264

(22) Filed: Dec. 23, 2025

(30) Foreign Application Priority Data
Mar. 31, 2025 (KR) 10-2025-0041585

(51) Int. Cl. H10K 59/80; H10K 59/122; H10K 59/38; H10K 102/00

(52) U.S. Cl. CPC H10K 59/879; H10K 59/122; H10K 59/38; H10K 59/80515; H10K 59/80521; H10K 59/8792; H10K 2102/351

(57) ABSTRACT

A display device includes a substrate having a plurality of sub-pixels, a first overcoating layer disposed on the substrate, a second overcoating layer including a bottom surface layer disposed on the first overcoating layer and a protruding portion protruded at least partially from the bottom surface layer, an anode disposed on a top surface of the protruding portion of the second overcoating layer, an organic layer disposed on the anode, and a cathode disposed on the organic layer corresponding to the top surface and the side surface of the protruding portion, in which a refractive index of the first overcoating layer is smaller than a refractive index of the second overcoating layer.

### CROSS REFERENCE TO RELATED APPLICATION

This application claims priority from and the benefit of Korean Patent Application No. 10-2025-0041585, filed on Mar. 31, 2025, which is hereby incorporated by reference for all purposes as if fully set forth herein.

### BACKGROUND

### Field

Embodiments of the invention relate generally to a display device.

### Discussion of the Background

In the information age, the field of display devices that visually display electrical information signals is rapidly growing. Ongoing research focuses on achieving features such as thinning, weight reduction, and low power consumption across various types of display devices.

An electroluminescent display device represented by an organic light emitting display device is a self-emitting display device and does not require a separate light source unlike a liquid crystal display device. Therefore, the electroluminescent display device can be manufactured to have a light weight and a small thickness. In addition, the electroluminescent display device is expected to be widely used across various fields due to its excellent in color reproduction, fast response speeds, wide viewing angles, and high contrast ratios (CRs).

In the conventional electroluminescent display device, however, some light may not escape from the display panel and remain trapped inside the display panel, which reduces the light extraction efficiency of the electroluminescent display device.

The above information disclosed in this Background section is only for understanding of the background of the inventive concepts, and, therefore, it may contain information that does not constitute prior art.

### SUMMARY

A display device according to embodiments of the invention is capable of improving light extraction efficiency.

A display device according to embodiments of the invention provides an improved light extraction efficiency and a longer lifespan.

Additional features of the inventive concepts will be set forth in the description which follows, and in part will be apparent from the description, or may be learned by practice of the inventive concepts.

According to one embodiment of the present disclosure, a display device includes a substrate having a plurality of sub-pixels, a first overcoating layer disposed on the substrate, a second overcoating layer including a bottom surface layer disposed on the first overcoating layer and a protruding portion protruded at least partially from the bottom surface layer, an anode disposed on a top surface of the protruding portion of the second overcoating layer, an organic layer disposed on the anode, and a cathode disposed on the organic layer corresponding to the top surface and the side surface of the protruding portion, and a refractive index of the first overcoating layer is smaller than a refractive index of the second overcoating layer.

The refractive index of the first overcoating layer may be in a range from about 1.30 to about 1.45.

The difference between the refractive index of the first overcoating layer and the refractive index of the second overcoating layer may be about 0.2 or more.

The first overcoating layer may include a siloxane-based resin.

The protruding portion may have a shape protruding corresponding to an emission area of the sub-pixel.

A bank may be disposed on a part of a top surface of the second overcoating layer spaced apart from the protruding portion.

The organic layer may extend to be in contact with the side surface of the protruding portion, and the cathode may include a first area positioned on the top surface of the protruding portion, and a second area extending from the first area and disposed on the organic layer corresponding to the side surface of the protruding portion.

A bank may be disposed on a part of the top surface of the protruding portion, the side surface of the protruding portion, and a part of a top surface of the second overcoating layer to cover an edge of the anode, in which a thickness of the bank is smaller than a thickness of the protruding portion.

The organic layer may be disposed on the bank corresponding to the side surface of the protruding portion, and the cathode may include a first area located on the top surface of the protruding portion, and a second area extending from the first area and disposed on the organic layer corresponding to the side surface of the protruding portion, and the second area of the cathode is spaced apart from the side surface of the protruding portion.

A plurality of color filters respectively may be disposed on the substrate corresponding to an emission area of each of the plurality of sub-pixels, in which a thickness of each of the plurality of color filters is smaller than a thickness of the first overcoating layer.

An organic buffer layer may be disposed below the first overcoating layer, in which a refractive index of the organic buffer layer is greater than a refractive index of the first overcoating layer and less than a refractive index of the second overcoating layer.

The refractive index of the organic buffer layer may be in a range from about 1.45 to about 1.60, the refractive index of the first overcoating layer may be in a range from about 1.30 to about 1.45, and the refractive index of the second overcoating layer may be in a range from about 1.60 to about 1.70.

A plurality of color filters respectively may be disposed on the substrate corresponding to an emission area of each of the plurality of sub-pixels, in which each of the plurality of color filters may be disposed on a same layer as the organic buffer layer and is surrounded by the organic buffer layer, and a thickness of each of the plurality of color filters may be larger than a thickness of the organic buffer layer, and the first overcoating layer may cover the top and side surfaces of each of the plurality of color filters exposed by the organic buffer layer.

The thickness of the organic buffer layer may be in a range from about 0.5 μm to about 1.0 μm, and the thickness of the first overcoating layer may be in a range from about 1.0 μm to about 2.5 μm.

A thin film transistor may be disposed on the substrate; and a light shielding layer may be disposed between the substrate and the thin film transistor, in which the light shielding layer may not overlap the side surface of the protruding portion.

According to another embodiment of the present disclosure, A display device, includes: a display panel, in which the display panel includes: a substrate having a plurality of sub-pixels; a first overcoating layer disposed on the substrate; a second overcoating layer including a bottom surface layer disposed on the first overcoating layer and a protruding portion protruding at least partially from the bottom surface layer; an anode disposed on a top surface of the protruding portion of the second overcoating layer; an organic layer disposed on the anode; and a cathode disposed on the organic layer corresponding to the top surface and a side surface of the protruding portion, in which a refractive index of the first overcoating layer is smaller than a refractive index of the second overcoating layer.

It is to be understood that both the foregoing general description and the following detailed description are exemplary and explanatory and are intended to provide further explanation of the invention as claimed.

### BRIEF DESCRIPTION OF DRAWINGS

The accompanying drawings, which are included to provide a further understanding of the invention and are incorporated in and constitute a part of this specification, illustrate embodiments of the invention, and together with the description serve to explain the inventive concepts.

FIG. 1 is a schematic configuration diagram illustrating a display device according to one embodiment of the present disclosure.

FIG. 2 is a schematic plan view illustrating one unit pixel structure of a display device according to a first embodiment of the present disclosure.

FIG. 3A is a schematic cross-sectional view taken along line A-A′ in FIG. 2.

FIG. 3B is a schematic cross-sectional view taken along line B-B′ in FIG. 2.

FIG. 4 is a schematic cross-sectional view illustrating a second sub-pixel of the display device according to the second embodiment of the present disclosure.

FIG. 5 is a schematic cross-sectional view illustrating a first sub-pixel of a display device according to the second embodiment of the present disclosure.

FIGS. 6A and 6B are schematic cross-sectional views illustrating one sub-pixel of a display device according to a third embodiment of the present disclosure.

FIG. 7A is a schematic simulation result showing light emission according to a light emission incident angle in a comparative example.

FIG. 7B is a schematic simulation result showing light emission according to a light emission incident angle in the first embodiment of the present disclosure.

FIG. 7C is a schematic simulation result showing light emission according to a light emission incident angle in the second embodiment of the present disclosure.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the D1-axis, the D2-axis, and the D3-axis are not limited to three axes of a rectangular coordinate system, such as the x, y, and z-axes, and may be interpreted in a broader sense. For example, the D1-axis, the D2-axis, and the D3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

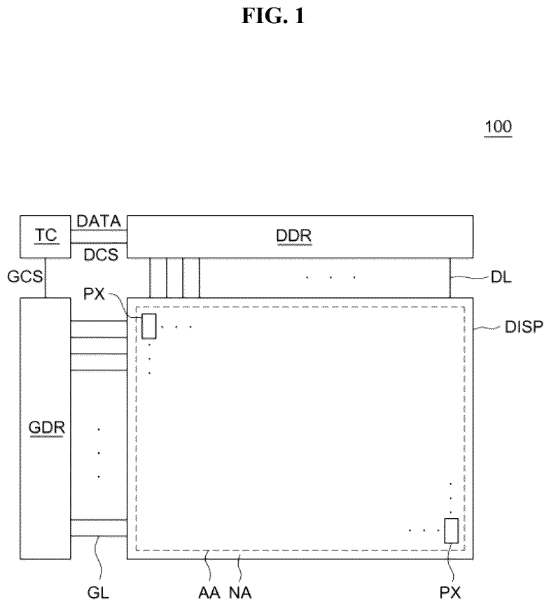

FIG. 1 is a schematic configuration diagram illustrating a display device according to one embodiment of the present disclosure.

A display device according to one embodiment of the present disclosure may include a display device, a lighting device, an electroluminescent display device, and the like. Hereinafter, for convenience of description, a display device will be mainly described. However, the following description may be equally applied to various other display devices such as a lighting device and an electroluminescent display device.

Referring to FIG. 1, a display device according to one embodiment of the present disclosure may include a display panel DISP configured to display an image or output light, and a driving circuit configured to drive the display panel DISP.

In the display panel DISP, multiple data lines DL and multiple gate lines GL may be disposed. A plurality of data lines DL and a plurality of gate lines GL of the display panel DISP may be disposed to cross each other. For example, the plurality of gate lines GL may be arranged in a row or column unit, and the plurality of data lines DL may be arranged in a column or row unit. Hereinafter, for convenience of description, it is assumed that a plurality of gate lines GL is disposed in a row and a plurality of data lines DL is disposed in a column.

In the display panel DISP, other types of signal lines may be disposed in addition to the plurality of data lines DL and the plurality of gate lines GL according to a sub-pixel structure. For example, a driving voltage line, a reference voltage line, or a common voltage line may be further disposed.

The display panel DISP may be various types of panels such as an LCD (Liquid Crystal Display) panel and an OLED (Organic Light Emitting Diode) panel.

The types of signal lines disposed in the display panel DISP may vary depending on the sub-pixel structure, the panel type, and the like. In addition, the signal line may be a concept including an electrode to which a signal is applied.

The display panel DISP may include a display area AA in which an image is displayed and a non-display area NA in which an image is not displayed outside the display area AA. Here, the non-display area NA may be also referred to as a bezel area.

A plurality of unit pixels PX for image display may be disposed in the display area AA. The plurality of unit pixels PX may be arranged in a matrix type defined by a plurality of data lines DL and a plurality of gate lines GL and include a plurality of sub-pixels as elements for displaying one color. In the display area AA, a pixel PX including an emission area for displaying an image and a driving circuit for driving the pixel PX may be disposed.

A pad unit for electrically connecting the data driver DDR may be disposed in the non-display area NA, and a plurality of data link lines for connection between the pad unit and the plurality of data lines DL may be disposed. Here, the plurality of data link lines may be portions in which the plurality of data lines DL extends to the non-display area NA, or may be separate patterns electrically connected to the plurality of data lines DL.

Further, in the non-display area NA, gate driving related lines for transmitting a voltage required for gate driving to the gate driver GDR through a pad unit to which the above-described data driver DDR is electrically connected may be disposed. For example, the gate driving-related lines may include a clock line for transmitting a clock signal, a gate voltage line for transmitting a gate voltage, and a gate driving control signal line for transmitting various control signals required for generating a scan signal. The gate driving related lines may be disposed in the non-display area NA, unlike the gate line GL disposed in the display area AA.

Further, the driving circuit may include, for example, a data driver DDR that drives a plurality of data lines DL, a gate driver GDR that drives a plurality of gate lines GL, a timing controller TC that controls the data driver DDR and the gate driver GDR.

As described above, the data driver DDR may drive a plurality of data lines DL by outputting data voltages to the plurality of data lines DL.

Further, the gate driver GDR may drive a plurality of gate lines GL by outputting scan signals to the plurality of gate lines GL.

For example, the timing controller TC may supply various control signals DCS and GCS required for driving operations of the data driver DDR and the gate driver GDR to control driving operations of the data driver DDR and the gate driver GDR. The timing controller TC may supply the image data DATA to the data driver DDR.

The timing controller TC may start scanning according to a timing implemented in each frame, output image data DATA converted to a data signal format used by the data driver DDR from input image data input from the outside, and control data driving at an appropriate time according to the scanning.

For example, the timing controller TC may receive timing signals, such as a vertical synchronization signal, a horizontal synchronization signal, an input data enable signal, and a clock signal, from the outside to control the data driver DDR and the gate driver GDR and generates various control signals to output the timing signals to the data driver DDR and the gate driver GDR. Further, in order to control the gate driver GDR, the timing controller TC may output various gate control signals GCS including a gate start pulse GSP, a gate shift clock GSC, a gate output enable signal GOE, and the like. In addition, in order to control the data driver DDR, the timing controller TC may output various data control signals DCS including a source start pulse SSP, a source sampling clock (SSC), and a source output enable signal (SOE).

The timing controller TC may be implemented as a component separate from the data driver DDR, or may be integrated with the data driver DDR and implemented as an integrated circuit.

The data driver DDR may receive the image data DATA from the timing controller TC and may supply a data voltage to a plurality of data lines DL to drive a plurality of data lines DL. The data driver DDR may be also referred to as a source driver.

The data driver DDR may exchange various signals with the timing controller TC through various interfaces.

Further, the gate driver GDR may sequentially drive the plurality of gate lines GL by sequentially supplying scan signals to the plurality of gate lines GL. Here, the gate driver GDR is also referred to as a scan driver.

The gate driver GDR may sequentially supply scan signals of an on voltage or an off voltage to a plurality of gate lines GL under the control of the timing controller TC.

When a specific gate line is opened by the gate driver GDR, the data driver DDR may convert the image data DATA received from the timing controller TC into an analog data voltage and supply the analog data voltage to the plurality of data lines DL.

The data driver DDR may be located only on one side of the display panel DISP, or in other embodiments, may be located on both sides of the display panel DISP according to a driving method, a panel design method, or the like. For example, the data driver DDR may be positioned above or below the display panel DISP, or may be positioned both above and below the display panel DISP.

The gate driver GDR may be located only on one side of the display panel DISP, or in other embodiments, may be located on both sides of the display panel DISP according to a driving method, a panel design method, or the like. For example, the gate driver GDR may be located on the left or right side of the display panel DISP, or may be located on both left and right sides.

The data driver DDR may be implemented by including one or more source driver integrated circuits (SDICs).

For example, each source driver integrated circuit may include a shift register, a latch circuit, a digital to analog converter (DAC), an output buffer, and the like. The data driver DDR may further include one or more analog to digital converters (ADC) in other embodiments.

Further, each source driver integrated circuit may be connected to a bonding pad of the display panel DISP in a tape automated bonding (TAB) type or a chip on glass (COG) type or disposed (or directly disposed) on the display panel DISP. In other embodiments, each source driver integrated circuit may be integrated and disposed on the display panel DISP. Further, each source driver integrated circuit may be implemented as a chip on film (COF) type. In this case, each source driver integrated circuit is mounted on the circuit film to be electrically connected to the data line DL in the display panel DISP through the circuit film.

The gate driver GDR may be configured by a plurality of gate driving circuits. Here, each of the plurality of gate driving circuits may correspond to the plurality of gate lines GL.

For example, each gate driving circuit may include a shift register, a level shifter, and the like.

The gate driving circuit may be electrically connected to the bonding pad of the display panel DISP in a tape automated bonding (TAB) type or a chip on glass (COG) type. Further, each gate driving circuit may be implemented as a chip on film (COF) type. In this case, each gate driving circuit is mounted on the circuit film to be electrically connected to the gate line GL in the display panel DISP through the circuit film. Further, each gate driving circuit is implemented as a gate in panel (GIP) type to be embedded in the display panel DISP. For example, each gate driving circuit may be directly formed on the display panel DISP.

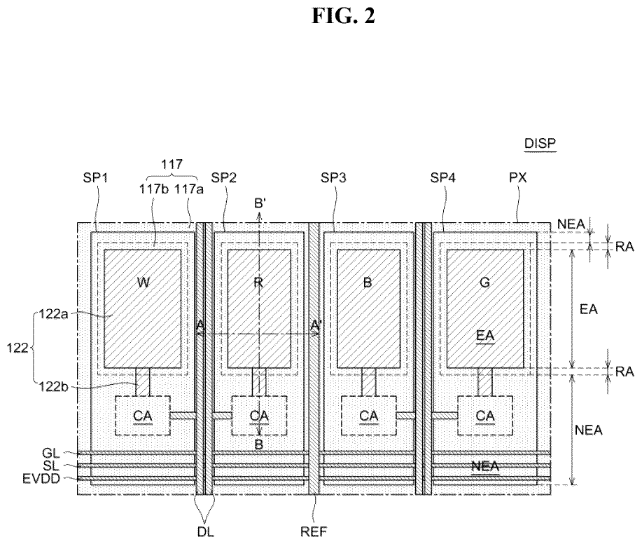

FIG. 2 is a schematic plan view illustrating one unit pixel structure of a display device according to a first embodiment of the present disclosure.

FIG. 2 illustrates a part of one unit pixel PX including the display panel DISP as an example and illustrates a second overcoating layer 117 including a protruding portion 117b and an anode 122 defining the emission area EA1.

Referring to FIG. 2, the display panel DISP according to the first embodiment of the present disclosure may include a pixel area in which a plurality of unit pixels PX is present and a line area in which various signal lines are disposed around the pixel area.

A plurality of unit pixels PX in which an image is substantially displayed may be disposed in the pixel area. Each of the plurality of unit pixels PX may include a first sub-pixel SP1, a second sub-pixel SP2, a third sub-pixel SP3, and a fourth sub-pixel SP4 which emit different color light. Each of the first sub-pixel SP1, the second sub-pixel SP2, the third sub-pixel SP3, and the fourth sub-pixel SP4 may be an element for displaying one color, and include an emission area in which light is emitted and a non-emission area in which light is not emitted. According to one embodiment of the present disclosure, only an emission area from which light is emitted may be defined as a sub-pixel. For example, each of the plurality of sub-pixels may display any one color of white, red, green, and blue, but is not limited thereto. For example, the first sub-pixel SP1 may be a white sub-pixel W. For example, the second sub-pixel SP2 may be a red sub-pixel R. For example, the third sub-pixel SP3 may be a blue sub-pixel B. For example, the fourth sub-pixel SP4 may be a green sub-pixel G. However, the present disclosure is not limited to the particular arrangement of the plurality of sub-pixels SP1, SP2, SP3, and SP4.

For example, the first sub-pixel SP1, the second sub-pixel SP2, the third sub-pixel SP3, and the fourth sub-pixel SP4 may have a polygonal shape such as a rectangular shape or a square shape, but are not limited thereto and may have various shapes such as a circular shape or an oval shape. Here, the shape of the sub-pixels SP1, SP2, SP3, and SP4 may be defined in the form of the anode 122 (specifically, the first area 122a of the anode 122), but is not limited thereto.

In FIG. 2, it is illustrated that one first sub-pixel SP1, one second sub-pixel SP2, one third sub-pixel SP3, and one fourth sub-pixel SP4 are gathered to form one unit pixel PX. However, embodiments of the present disclosure are not limited thereto.

Referring to FIG. 2, each of the first sub-pixel SP1, the second sub-pixel SP2, the third sub-pixel SP3, and the fourth sub-pixel SP4 may include an emission area EA, a non-emission area NEA, and a reflection area RA interposed between the emission area EA and the non-emission area NEA.

The emission area EA may be an area where light is emitted, and be an area defined by the anode 122 in the sub-pixels SP1, SP2, SP3, and SP4. The emission area EA may be disposed in each of the sub-pixels SP1, SP2, SP3, and SP4. In this case, the emission areas EA in the sub-pixels SP1, SP2, SP3, and SP4 may have different sizes or areas. For example, the emission areas EA in the second sub-pixel SP2 and the third sub-pixel SP3, which are the red sub-pixel R and the blue sub-pixel B, may have a smaller area than the emission areas EA in the first sub-pixel SP1 and the fourth sub-pixel SP4, which are the white sub-pixel W and the green sub-pixel G. Referring to FIG. 2, the second sub-pixel SP2 and the third sub-pixel SP3 may have a smaller width than those of the first sub-pixel SP1 and the fourth sub-pixel SP4.

Referring to FIG. 2, the emission area EA may have an approximately (or overall) polygonal shape, such as a rectangular shape, when viewed from the top, but is not limited thereto.

The non-emission area NEA may be an area where light is not emitted, and may be defined as a remaining area excluding the emission area EA in each of the sub-pixels SP1, SP2, SP3, and SP4.

The non-emission area NEA may include a circuit area CA. The circuit area CA may be spatially separated from the emission area EA in each of the sub-pixels SP1, SP2, SP3, and SP4. The circuit area CA may include a driving thin film transistor, a switching thin film transistor, and a capacitor configured to drive the light emitting elements of the sub-pixels SP1, SP2, SP3, and SP4. The circuit area CA may be disposed adjacent to the emission area EA.

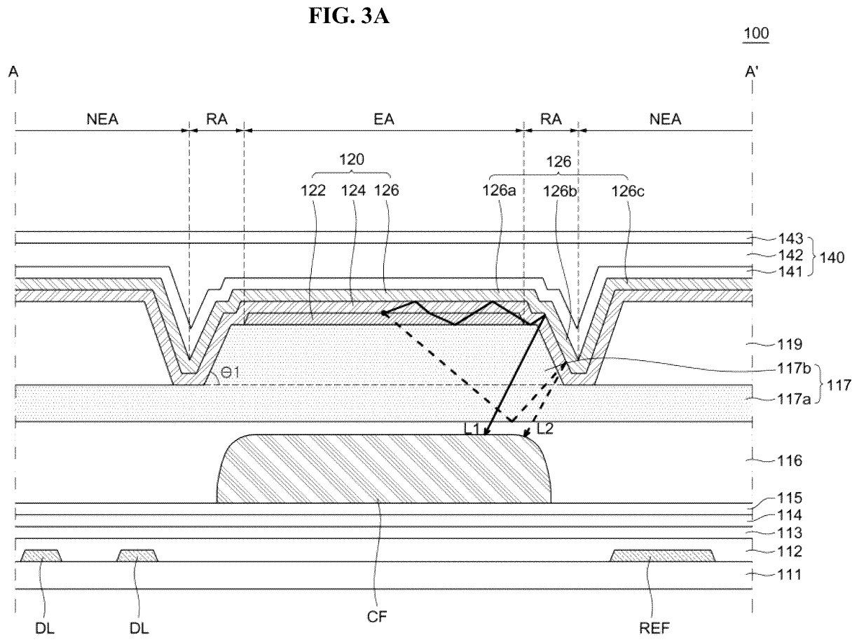

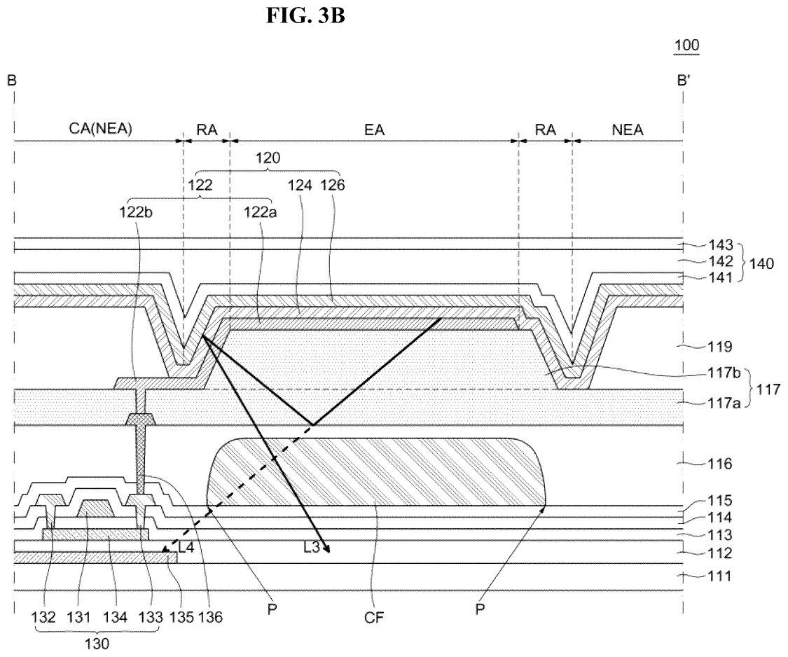

The reflective area RA may be an area in which light emitted from the emission area EA is reflected by a side mirror (SM) structure of the cathode. The reflective area RA may be disposed adjacent to the emission area EA. In addition, the reflective area RA may be located to surround the emission area EA, but is not limited thereto. The reflective area RA may be disposed to overlap at least a portion of the protruding portion 117b of the second overcoating layer 117. A detailed description related to the SM structure of the cathode disposed in the reflective area RA will be described in detail with reference to FIGS. 3A and 3B.

Various signal lines configured to control the sub-pixels SP1, SP2, SP3, and SP4 may be disposed in the line area. For example, two data lines DL may be disposed in parallel with each other between the first sub-pixel SP1 and the second sub-pixel SP2 and between the third sub-pixel SP3 and the fourth sub-pixel SP4. A common voltage line EVDD, a gate line GL, and a sensing line SL extending (or horizontally extending) in a direction perpendicular to the extending (or vertically extending) direction of the data line DL may be disposed below the emission area EA and the circuit area CA of each of the first to fourth sub-pixels SP1 to SP4. A reference voltage line REF extending in the same direction as the data line DL may be disposed between the second sub-pixel SP2 and the third sub-pixel SP3. The reference voltage line REF may be used as a sensing line for externally sensing a change in characteristics of the driving thin film transistor and/or a change in characteristics of the light emitting element layer disposed in the circuit area CA in the sensing driving mode of the sub-pixel.

FIG. 3A is a schematic cross-sectional view taken along line A-A′ in FIG. 2. FIG. 3B is a schematic cross-sectional view taken along line B-B′ in FIG. 2. FIG. 3A illustrates a part of a cross-section of a red sub-pixel cut in a left-right direction in the first embodiment of the present disclosure. FIG. 3B illustrates a part of a cross-section of the red sub-pixel cut in the vertical direction in the first embodiment of the present disclosure.

FIG. 3A and FIG. 3B do not illustrate the components disposed on the light emitting element 120 for the convenience of description. However, the present disclosure may include an encapsulation structure disposed on the light emitting element 120.

Referring to FIGS. 3A and 3B, the buffer layer 112 may be disposed on the substrate 111.

Recently, a flexible substrate 111 may be made of a flexible material having a flexible characteristic such as plastic.

The substrate 111 may be in the form of a film including one of a group including a polyester-based polymer, a silicon-based polymer, an acrylic polymer, a polyolefin-based polymer, and a copolymer thereof.

The substrate 111 may include a first substrate, a second substrate, and an insulating film. An insulating film may be disposed between the first substrate and the second substrate. As described above, the substrate 111 may be configured by the first substrate, the second substrate, and the insulating film to prevent moisture permeation. For example, the first substrate and the second substrate may be polyimide (PI) substrates.

Various signal lines, such as a data line DL, a reference voltage line REF, or a common voltage line, may be disposed on the substrate 111. Embodiments of the present disclosure are not limited thereto, and the data line DL, the reference voltage line REF, or the common voltage line may be disposed on the buffer layer 112. For example, the data line DL, the reference voltage line REF, or the common voltage line may be disposed in the non-emission area NEA.

The buffer layer 112 may be disposed on the substrate 111. The buffer layer 112 may protect the semiconductor layer 134 and block various types of defects introduced from the substrate 111. For example, the buffer layer 112 may be formed of amorphous silicon, silicon nitride (SiNₓ), silicon oxide (SiOₓ), or the like. The buffer layer 112 may be a multi-buffer layer formed by alternately stacking silicon nitride (SiNₓ) and silicon oxide (SiOₓ) at least once, and may delay the diffusion of moisture or oxygen permeating the substrate 111.

The driving thin film transistor 130 may be disposed on the buffer layer 112. The driving thin film transistor 130 may be disposed in the circuit area CA in the non-emission area NEA.

Specifically, the semiconductor layer 134 may be disposed in the circuit area CA and disposed on the substrate 111.

For example, the semiconductor layer 134 may be formed of a polycrystalline semiconductor and may include a channel region, a source region, and a drain region. Embodiments of the present disclosure are not limited thereto, and the semiconductor layer 134 may be made of amorphous silicon or an oxide semiconductor.

The gate insulating layer 113 may be disposed on the semiconductor layer 134. For example, the gate insulating layer 113 may be disposed on the semiconductor layer 134 and the buffer layer 112.

The gate insulating layer 113 may be configured by a single layer of silicon nitride (SiNₓ) or silicon oxide (SiOₓ) or a multi-layer thereof, but is not limited thereto.

A gate line may be disposed in a first direction on the gate insulating layer 113, and a gate electrode 131 electrically connected to the gate line may be disposed. The present disclosure is not limited thereto, and the gate line may be disposed on the substrate 111 together with the data line DL.

The gate electrode 131 may be disposed on the gate insulating layer 113 to overlap the semiconductor layer 134 in a thickness direction.

For example, the gate electrode 131 and the gate line may be configured by a single layer or multiple layers of conductive metals such as copper (Cu), aluminum (Al), molybdenum (Mo), chromium (Cr), gold (Au), titanium (Ti), nickel (Ni), and neodymium (Nd), without being limited thereto.

An interlayer insulating layer 114 may be disposed on the gate electrode 131 and configured to cover the gate electrode 131.

For example, the interlayer insulating layer 114 may be configured by a single layer of silicon nitride (SiNₓ) or silicon oxide (SiOₓ) or a multi-layer thereof, but is not limited thereto.

In this case, a contact hole exposing both ends of the semiconductor layer 134 may be formed by selectively removing a portion of the interlayer insulating layer 114 and the gate insulating layer 113.

Further, the source electrode 132 and the drain electrode 133 respectively electrically connected to both ends of the semiconductor layer 134 may be disposed on the interlayer insulating layer 114.

The protective layer 115 may be disposed on the source electrode 132 and the drain electrode 133. The protective layer 115 may be omitted in other embodiments. The protective layer 115 may be disposed so that a part of the source electrode 132 or the drain electrode 133 of the thin film transistor 130 is exposed.

The protective layer 115 may be configured by a single layer of silicon nitride (SiNₓ) or silicon oxide (SiOₓ) or a multi-layer thereof, but is not limited thereto.

A color filter CF may be disposed on the protective layer 115. The color filter CF is for converting a color of light emitted from the light emitting element 120 and may be one of a red color filter, a green color filter, and a blue color filter. For example, a red color filter may be disposed in the red sub-pixel or a color filter may not be disposed. Meanwhile, a white color filter may be disposed in the white sub-pixel or the color filter may not be disposed.

The color filter CF may be formed of a material having a refractive index of about 1.5.

The thickness of the color filter CF may be about 1.0 μm or more or about 2.0 μm or more or in the range from about 2.5 μm to about 4.0 μm, but is not limited thereto.

Overcoating layers 116 and 117 may be disposed on the protective layer 115 and the color filter CF.

The overcoating layers 116 and 117 may have a multilayer structure including at least two layers, and for example, may include a first overcoating layer 116 and a second overcoating layer 117.

The first overcoating layer 116 may be disposed on the protective layer 115 and the color filter CF. For example, the first overcoating layer 116 may be disposed to cover the protective layer 115 and the color filter CF. In particular, the first overcoating layer 116 may be disposed to be in contact with the top surface and the side surface of the color filter CF. Accordingly, the first overcoating layer 116 may serve as a planarization layer.

The thickness of the first overcoating layer 116 may be in the range from about 1.0 μm to about 3.0 μm or about 2 μm, but is not limited thereto. The first overcoating layer 116 may be formed to have a thickness sufficient to cover the color filter CF.

The refractive index of the first overcoating layer 116 may be smaller than the refractive index of the second overcoating layer 117. For example, the refractive index of the first overcoating layer 116 may be about 1.50 or less or about 1.40 or in the range from about 1.30 to about 1.45 or about 1.40, but is not limited thereto. Further, a difference between the refractive index of the first overcoating layer 116 and the refractive index of the second overcoating layer 117 may be greater than or equal to about 0.2. When the refractive index of the first overcoating layer 116 satisfies the above range, the effect of extracting light in the front direction may be further improved.

Specifically, when the refractive index of the first overcoating layer 116 is about 0.2 or more different from that of the second overcoating layer 117 positioned thereon, the total reflection of light incident from the second overcoating layer 117 to the first overcoating layer 116 is increased so that the amount of light reflected on the side mirror structure of the cathode to be described below is increased so that the luminous efficiency and luminance may be finally improved. A specific light efficiency improvement effect according to the refractive index of the overcoating layers 116 and 117 will be described later.

The first overcoating layer 116 may be made of an organic material that satisfies the above-described refractive index. For example, the first overcoating layer 116 may be formed of a material having a refractive index of about 1.50 or less or about 1.40 or less. For example, the first overcoating layer 116 may be made of one or more materials among siloxane-based resin, acrylic resin, epoxy resin, phenolic resin, polyamide-based resin, polyimide-based resin, unsaturated polyester-based resin, polyphenylene-based resin, and benzocyclobutene, but is not limited thereto. More specifically, the first overcoating layer 116 may include a siloxane-based resin containing no fluorine. The siloxane-based resin may form an ultra-low refractive overcoating layer having a low refractive index of about 1.40 or less.

The first overcoating layer 116 may be formed from a composition including a base resin, a photopolymerizable monomer, and a photoinitiator. For example, the base resin may be made of a siloxane-based resin. The siloxane-based resin has a low refractive index and forms a network structure with a photopolymerizable monomer to enhance the stability of the resin formed after curing. The siloxane-based resin may include, but is not limited to, polymethylvinyl siloxane, poly(methylphenylphenyl) siloxane, and poly(phenylvinyl)-co-(methylvinyl) silsesquioxane.

As the photopolymerizable resin, an epoxy-based monomer may be used. The epoxy-based monomer suppresses the shrinkage of the siloxane-based resin during curing and forms a network structure, thereby contributing to flexible and stable film forming. For example, when a siloxane-based resin is used as the base resin, an epoxy monomer represented by the following formula 1 may be used to increase flexibility after curing.

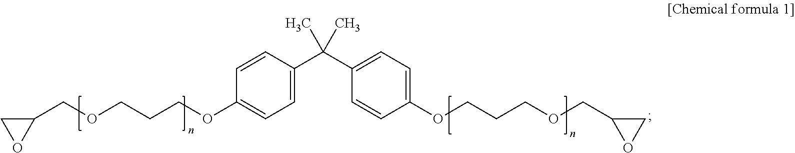

In Formula 1, n may be 1 to 10.

The photoinitiator may include an oxime compound, an acetophenone compound, a thioxanthone compound, a benzophenone compound, or a combination thereof, but is not limited thereto.

A connection electrode 136 configured to electrically connect the driving thin film transistor 130 and the light emitting element 120 may be disposed on the first overcoating layer 116. The connection electrode 136 may be formed of a material made of copper (Cu), aluminum (Al), molybdenum (Mo), chromium (Cr), gold (Au), titanium (Ti), nickel (Ni), neodymium (Nd), or an alloy thereof, but is not limited thereto. Even FIG. 3B exemplarily illustrates that the connection electrode 136 is disposed above the first overcoating layer 116, embodiments are not limited thereto. For example, the connection electrode 136 may be disposed on the protective layer 115 in some embodiments.

The second overcoating layer 117 may be disposed on the first overcoating layer 116.

In the display panel DISP of the first embodiment of the present disclosure, the overcoating layers 116 and 117 may be formed of two layers, which is due to an increase in various signal lines and a thickness of the color filter CF as the display panel DISP has a higher resolution. Accordingly, since it is difficult to displace all lines on one layer while maintaining a minimum interval, and it is difficult to cover a top surface of the color filter CF, an additional layer may be formed. Due to the addition of such an additional layer, for example, the second overcoating layer 117, there is room for line arrangement, which may facilitate line/electrode arrangement design, and planarize the upper portion of the color filter CF to facilitate formation of a light emitting element. Further, when a dielectric material is used as the multi-layered overcoating layer (116, 117), the overcoating layer (116, 117) may also be used for forming a capacitance between the metal layers.

The second overcoating layer 117 may be formed to expose a part of the connection electrode 136, and the drain electrode 133 of the driving thin film transistor 130 and the anode 122 of the light emitting element 120 may be electrically connected by the connection electrode 136.

A refractive index of the second overcoating layer 117 may be greater than a refractive index of the first overcoating layer 116. For example, the refractive index of the second overcoating layer 117 may be about 1.50 or more or about 1.60 or in the range from about 1.50 to 1.70 or in the range from about 1.60 to about 1.70, but is not limited thereto. Further, a difference between the refractive index of the second overcoating layer 117 and the refractive index of the first overcoating layer 116 may be greater than or equal to about 0.2. When the refractive index of the second overcoating layer 117 satisfies the above range, the amount of total reflection light between the first overcoating layer 116 and the second overcoating layer 117 may be increased. Accordingly, the amount of light reflected on the side mirror structure of the cathode may be increased, thereby finally improving light efficiency and luminance.

According to the first embodiment of the present disclosure, the second overcoating layer 117 may include a bottom surface layer 117a and a protruding portion 117b. The bottom surface layer 117a may be disposed on the first overcoating layer 116 in the entire emission area EA, the non-emission area NEA, and the reflection area RA. The protruding portion 117b may be disposed on the bottom surface layer 117a and protrude corresponding to the emission area EA of the sub-pixel. A top surface of the protruding portion 117b of the second overcoating layer 117 may correspond to the first area 122a of the anode 122.

The protruding portion 117b may include a top surface, a side surface, and a bottom surface. The protruding portion 117b may have trapezoidal shape when viewed from a side. In this case, the length of top surface may be less than the length of the bottom surface.

The top surface of the protruding portion 117b may be the uppermost surface of the second overcoating layer 117, and may be substantially parallel to the substrate 111. The top surface of the protruding portion 117b may correspond to the emission area EA. The top surface of the protruding portion 117b may have an approximately (or overall) polygonal shape, such as a rectangular shape, when viewed from the top in substantially the same manner as the emission area EA.

The side surface of the protruding portion 117b may extend laterally from the top surface of the protruding portion 117b. For example, the side surface of the protruding portion 117b may include a taper having a predetermined angle. In FIGS. 3A and 3B, it is illustrated as an example that a portion where the top surface and the side surface of the protruding portion 117b meet each other in a straight line shape forms a vertex, but the present disclosure is not limited thereto, and the side surface of the protruding portion 117b may have a gentle curve.

Further, the bottom surface of the protruding portion 117b may be a surface which meets the bottom surface layer 117a and may be substantially parallel to the substrate 111. The lower surface of the protruding portion 117b may have an approximately (or overall) polygonal shape such as a rectangular shape when viewed from the top. The present disclosure is not limited thereto, and the upper and lower surfaces of the protruding portion may have various shapes such as a circular shape or an oval shape.

The bottom surface layer 117a and the protruding portion 117b of the second overcoating layer 117 may be integrally formed of the same material, without being limited thereto. The bottom surface layer 117a and the protruding portion 117b may be formed of different materials by different processes.

For example, the protruding portion 117b may have a thickness in the range from about 1.0 μm to about 1.5 μm, but is not limited thereto.

For example, the side portion of the protruding portion 117b may have a taper in the range from about 30 degrees to about 60 degrees or in the range from about 40 degrees to about 70 degrees or about 45 degrees or about 60 degrees or about 45 degrees to form a side mirror structure of the cathode 126, but is not limited thereto.

The second overcoating layer 117 may be formed of an organic material that satisfies the above-described refractive index. For example, the second overcoating layer 117 may be formed of a material having a refractive index of about 1.50 or more or about 1.60 or more. For example, the second overcoating layer 117 may be made of one or more materials of acrylic resin, epoxy resin, phenolic resin, polyamides resin, polyimides resin, unsaturated polyesters resin, polyphenylene resin, benzocyclobutene, and polyphenylene sulfide resin. However, the present disclosure is not limited thereto.

The anode 122 may be disposed to correspond to each of the plurality of sub-pixels SP1, SP2, SP3, and SP4. In particular, the anode 122 may be disposed to be separated for each of the plurality of sub-pixels SP1, SP2, SP3, and SP4. The anode 122 may be made of a transparent conductive material such as indium-tin-oxide (ITO) or indium-zinc-oxide (IZO) so that light emitted from the light emitting element 120 is emitted to the outside through the substrate 111 disposed on the rear surface. Further, the anode 122 may be a component for supplying holes to the organic layer 124 and may be made of a material having a high work function. The anode 122 may have a single layer or a multi-layer structure. In the case of a multi-layer structure, it is possible to adjust the light distribution using a difference in refractive index by using materials having different refractive indices. For example, in a multilayer structure, the lower layer may have a larger refractive index than the upper layer.

Some portions of the anode 122 may be partially disposed on a top surface of the bottom surface layer 117a of the second overcoating layer 117, and the other portions of the anode 122 may be partially disposed on a top surface and a side surface of the protruding portion 117b. For example, the anode 122 disposed in the emission area EA may be in contact with the top surface of the protruding portion 117b of the second overcoating layer 117.

The anode 122 may include a first area 122a which is disposed on a part of the top surface of the protruding portion 117b of the second overcoating layer 117 and whose surface is substantially parallel to the surface of the substrate 111, and a second area 122b which extends from the first area 122a to the top surface of the bottom surface layer 117a of the second overcoating layer 117. For example, when viewed from the top, the second area 122b may have a shape elongated from the lower edge of the emission area EA, but is not limited thereto. Further, the second area 122b may be disposed in the non-emission area NEA and disposed in the circuit area CA to overlap at least a part of the driving thin film transistor 130.

For example, the second area 122b of the anode 122 may be spaced apart from the neighboring second area 122b by a predetermined distance to prevent a short between neighboring sub-pixels.

As described above, in one sub-pixel, the second overcoating layer 117 may include at least one contact hole spaced apart from the protruding portion 117b, and the drain electrode 133 of the driving thin film transistor 130 may be electrically connected to the second area 122b of the anode 122 through the contact hole.

The light shielding layer 135 may be disposed between the substrate 111 and the driving thin film transistor 130. The light shielding layer 135 may be disposed in the circuit area CA. The light shielding layer 135 may serve as a light shield. Accordingly, the light shielding layer 135 (which can be also referred to as a light blocking layer) may be disposed in the non-emission area NEA. The light shielding layer 135 may be disposed in the non-emission area NEA and disposed not to overlap the emission area EA and the reflection area RA.

Specifically, the semiconductor layer 134 may be disposed in the circuit area CA above the substrate 111.

The bank 119 may be disposed on the second overcoating layer 117.

For example, the bank 119 may be disposed in the non-emission area NEA on the second overcoating layer 117.

In this case, the bank 119 may be disposed to be spaced apart from the emission area EA. In this case, the bank 119 may expose a part of the anode 122 positioned therebelow and a top surface of the second overcoating layer 117. Further, the bank 119 may be disposed to be spaced apart from a side surface of the protruding portion 117b of the second overcoating layer 117.

The top surface of the bank 119 may be located on the same plane as the top surface of the protruding portion 117b of the second overcoating layer 117 or may be located at a higher level. In this case, the bank 119 may be disposed to be spaced apart from the first area 122a of the anode 122 and the protruding portion 117b of the second overcoating layer 117 without covering the edge of the first area 122a of the anode 122 positioned on the top surface of the protruding portion 117b of the second overcoating layer 117, thereby forming a side mirror structure of the cathode 126 to be described later.

The bank 119 may have a side portion on the left and right sides of the emission area EA, and the side portion of the bank 119 may be a surface extending from the top surface to the side surface. The side portion of the bank 119 may include a taper having a predetermined angle. For example, the side portion of the bank 119 may include a taper having an angle of in the range from about 30° to about 65°, but is not limited thereto.

The bank 119 may be formed of an organic material. For example, the bank 119 may be formed of polyimide, acryl, or benzocyclobutene-based resin, but is not limited thereto. Further, the bank 119 may be formed of a black material. For example, the bank 119 may be configured by dispersing a black dye in an organic material, but is not limited thereto, and may be configured with any black material as long as it has a black color.

Meanwhile, the emission area EA may have a shape corresponding to the shape of the top surface of the protruding portion 117b. The fact that the shape of a component corresponds to the shape of another component may mean that the shape of a component has the same shape as another component, the shape is the same, but the size is different, or that the shape of a component is formed by transferring the shape of another component by some method. Accordingly, the shape of the emission area EA may be understood as being substantially transferred with the shape of the top surface of the protruding portion 117b by light emitted from the organic layer 124 positioned on the top surface of the protruding portion 117b.

In addition, the reflective area RA may be located adjacent to at least one side of the emission area EA without overlapping the light-emitting area EA. In FIGS. 3A and 3B, the reflective area RA may be positioned to surround the emission area EA. In addition, the reflective area RA may be a closed curve surrounding the emission area EA. Alternatively, the reflective area RA may have a shape in which a part of the closed curve is disconnected.

Sub-pixels may be distinguished by the emission area EA.

Further, a light emitting element 120 which is electrically connected to the connection electrode 136 through a contact hole may be disposed on the second overcoating layer 117.

In this case, for example, the light emitting element 120 may include an anode 122 electrically connected to the drain electrode 133 of the driving thin film transistor 130, a plurality of organic layers 124 disposed on the anode 122, and a cathode 126 disposed on the organic layer 124. The organic layer 124 may be referred to as a light emitting unit, and is not limited to the terminology.

As described above, the anode 122 may be made of a transparent conductive material.

In FIGS. 3A and 3B, for the convenience of description, it is illustrated as an example that the anode 122 is configured as a single layer, but the present disclosure is not limited thereto and may have a multi-layered structure.

The organic layer 124 may be disposed on the anode 122. In particular, the organic layer 124 may be disposed on the first area 122a.

For example, the organic layer 124 may include a hole injection layer, a hole transport layer, a light emitting layer, an electron transport layer, and an electron injection layer. In a tandem structure in which a plurality of light emitting layers overlap, a charge generation layer may be additionally disposed between the light emitting layer and the light emitting layer. For example, a common emission layer may be formed for each sub-pixel to emit white light regardless of color, and a color filter CF for distinguishing colors may be separately provided. In this case, each of the light emitting layers may be individually disposed, and a hole injection layer, an electron injection layer, a hole transport layer, or an electron transport layer may be provided as a common layer to be equally disposed for each sub-pixel.

Meanwhile, on the left and right sides of the emission area EA, the organic layer 124 may be disposed on the top surface of the first area 122a and the second area 122b of the anode 122, a part of the top surface of the protruding portion 117b of the second overcoating layer 117, and the side portion and the top surface of the bank 119.

Further, the cathode 126 may be disposed on the organic layer 124 so as to face the anode 122 with the organic layer 124 interposed therebetween.

The cathode 126 may be not separated for each of the plurality of sub-pixels, and may be configured as a common layer.

The cathode 126 may be formed of a metal material having a low work function to supply electrons to the organic layer 124. The cathode 126 may be made of a metal material having a high reflectance so as to reflect light emitted from the organic layer 124 toward the substrate 111. For example, the cathode 126 may be made of gold (Au), silver (Ag), aluminum (Al), molybdenum (Mo), and magnesium (Mg), or an alloy thereof, but is not limited thereto.

For example, the cathode 126 of the first embodiment of the present disclosure may include a first area 126a which is disposed in the emission area EA and whose surface is substantially parallel to the surface of the substrate 111, and a second area 126b which extends from the first area 126a and whose surface has a predetermined angle with respect to the substrate 111. Further, for example, the second area 126b of the cathode 126 may correspond to a side surface of the protruding portion 117b. Therefore, the second area 126b of the cathode 126 may be referred to as a side portion of the cathode 126.

The second area 126b of the cathode 126 may be disposed on the left and right sides of the emission area EA. For example, the second area 126b may be disposed in the reflective area RA. Further, the cathode 126 may further include a third area 126c extending in a sub-pixel direction adjacent to the second area 126b. For example, the third area 126c may be disposed above the bank 119 and in the non-emission area NEA. The third area 126c may be substantially parallel to the surface of the substrate 111, but is not limited thereto.

In the first embodiment of the present disclosure, the second area 126b of the cathode 126 is a portion having a side mirror shape, and may constitute a side mirror (SM) structure. For example, the SM structure of the cathode 126 may form the reflective area RA. For example, the reflective area RA follows the outline of the emission area EA. The reflective area RA may be in the form of a seamless frame or a discontinuous frame. In the case of a discontinuous frame shape, it may have a discontinuous shape in the middle while surrounding the outline of the emission area EA.

The second area 126b of the cathode 126 of the first embodiment of the present disclosure may be disposed on the side surface of the protruding portion 117b along the shape of the side surface of the protruding portion 117b. In this case, the second area 126b of the cathode 126 disposed on the side surface of the protruding portion 117b may include a taper having an angle in the range from about 30 degrees to about 60 degrees, but is not limited thereto. The second area 126b of the cathode 126 made of a metal material having a high reflectance may serve as a side mirror (SM). Accordingly, the emission area according to the first embodiment of the present disclosure may further include the reflective area RA by the side mirror structure in addition to the emission area EA. For example, the reflective area RA may be formed between the emission area EA and the non-emission area NEA corresponding to the first area 122a and the second area 122b of the anode 122.

In the first embodiment of the present disclosure, the side mirror structure by the cathode 126 formed by the protruding portion 117b of the second overcoating layer 117 forms the reflective area RA, and a part of the light emission by the light emitting element 120 is reflected from the second area 126b of the cathode 126 by the side mirror structure to form the frame-shaped reflective area RA. Accordingly, the light extraction efficiency may be improved.

As described above, the light extraction efficiency is improved by the SM structure of the cathode 126, in particular, the second area 126b. Specifically, light which is trapped in the substrate mode and the wave guide mode may be extracted through the second area 126b of the cathode 126. However, the light path in which the emission distribution angle is smaller than the angle (01 in FIG. 3A) of the second area 126b of the cathode 126 may not be extracted, and the taper of the second area 126b of the cathode 126 may be set to about 45 degrees. As described above, light below the corresponding angle may not be extracted according to the maximum taper angle of the second area 126b of the cathode 126, and in particular, blue has a higher absorption rate than red or green, so the light extraction efficiency may be further lowered.

More specifically, as illustrated in FIG. 3A, a part of the light emitted from the organic layer 124 may be guided through total reflection between the cathode 126 and the second overcoating layer 117 in the emission area EA and then reflected from the reflection area RA to change the optical path. Accordingly, the light whose path is formed in the reflective area RA by the second overcoating layer 117 may be reflected by the second area 126b of the cathode 126 in the reflective area RA to be emitted through the color filter CF located in the emission area EA. This is defined as the first reflected light L1 reflected from the reflective area RA after the path is changed by the second overcoating layer 117.

In the meantime, a light path of another part of the light emitted from the organic layer 124 and directed toward the substrate 111 may be changed toward the reflective area RA due to a difference in refractive index between the first overcoating layer 116 and the second overcoating layer 117. Accordingly, the light whose path may be formed in the reflective area RA by the first overcoating layer 116 is reflected by the second area 126b of the cathode 126 in the reflective area RA to be emitted through the color filter CF located in the emission area EA. This may be defined as the second reflected light L2 reflected from the reflective area RA after the path is changed by the first overcoating layer 116.

In the first embodiment of the present disclosure, the refractive index of the first overcoating layer 116 may be about 1.40 or less or a difference of about 0.2 or more from the refractive index of the second overcoating layer 117. Accordingly, the amount of light reflected between the first overcoating layer 116 and the second overcoating layer 117 increases, and the amount of light reflected by the second area 126b of the cathode 126 in the reflective area RA also increases. Accordingly, the light extraction efficiency may be improved.

Meanwhile, referring to FIG. 3B, light L4 having a specific angle or more may be shielded by the light shielding layer 135 positioned in the circuit area CA, among light emitted from the organic layer 124 and directed toward the substrate 111. However, in the first embodiment of the present disclosure, due to a difference in refractive index between the first overcoating layer 116 and the second overcoating layer 117, light L3 which may be blocked by the light shielding layer 135 may be reflected to the reflective area RA to be reflected again by the second area 126b of the cathode 126 to be emitted through the color filter CF. Therefore, the light which may be reduced by the circuit area CA is also emitted through the color filter CF to improve the light extraction efficiency. Meanwhile, in order to improve the front luminance, the light shielding layer 135 may not be disposed in the reflective area RA, and further, may be disposed so as not to overlap the side surface of the protruding portion 117b.

Meanwhile, referring to FIG. 3B, at least a part of the end portion P of the color filter CF may be disposed to overlap the reflective area RA. When the end portion P of the color filter CF is disposed to extend from the emission area EA to be positioned in the reflection area RA, the area of the color filter CF through which the light L2 and L3 reflected from the reflection area RA passes is maximized to improve the color reproduction rate and the emission efficiency. At this time, the end portion P of the color filter CF may be disposed not to overlap the light shielding layer 135, but is not limited thereto, so that the light emission efficiency is not lowered by the light shielding layer 135.

The encapsulation layer 140 may be located on the light emitting element 120.

Here, the encapsulation layer 140 may have a single layer structure or a multi-layer structure. For example, the encapsulation layer 140 may include a first encapsulation layer 141, a second encapsulation layer 142, and a third encapsulation layer 143. For example, the first encapsulation layer 141 and the third encapsulation layer 143 may be configured by inorganic films, and the second encapsulation layer 142 may be configured by an organic film. For example, among the first encapsulation layer 141, the second encapsulation layer 142, and the third encapsulation layer 143, the second encapsulation layer 142 is the thickest to serve as an overcoating layer.

The first encapsulation layer 141 may be made of an inorganic insulating material capable of low-temperature deposition. For example, the first encapsulation layer 141 may be made of silicon nitride (SiNₓ), silicon oxide (SiOₓ), silicon oxynitride (SiON), or aluminum oxide (Al₂O₃).

The second encapsulation layer 142 may be formed to have a smaller area than the first encapsulation layer 141. In this case, the second encapsulation layer 142 may be formed to expose both ends of the first encapsulation layer 141. For example, the second encapsulation layer 142 may be made of an organic insulating material such as acrylic resin, epoxy resin, polyimide, polyethylene, or silicon oxy carbon (SiOC). Further, for example, the second encapsulation layer 142 may be formed by an inkjet method, but is not limited thereto.

The third encapsulation layer 143 may be formed to cover upper and side surfaces of each of the second encapsulation layer 142 and the first encapsulation layer 141. The third encapsulation layer 143 may minimize or block the permeation of external moisture or oxygen into the first encapsulation layer 141 and the second encapsulation layer 142. For example, the third encapsulation layer 143 may be made of an inorganic insulating material, such as silicon oxide (SiOₓ), silicon oxynitride (SiON), aluminum oxide (Al₂O₃), or silicon nitride (SiNₓ).

In the display device according to the first embodiment of the present disclosure, light emitted laterally from the light emitting element is reflected through the side mirror structure of the cathode, thereby improving light efficiency and luminance. Further, in the overcoating layer having a two-layer structure disposed between the light emitting element and the color filter, the refractive index of the first overcoating layer therebelow may be about 1.40 or less or the refractive index of the first overcoating layer and the refractive index of the second overcoating layer positioned thereabove have a difference of about 0.2 or more, which may increase the amount of light reflected between the first overcoating layer and the second overcoating layer. Accordingly, light directed to the non-emission area is also reflected again through the side mirror structure of the cathode, so that the light extraction efficiency and the front luminance may be improved.

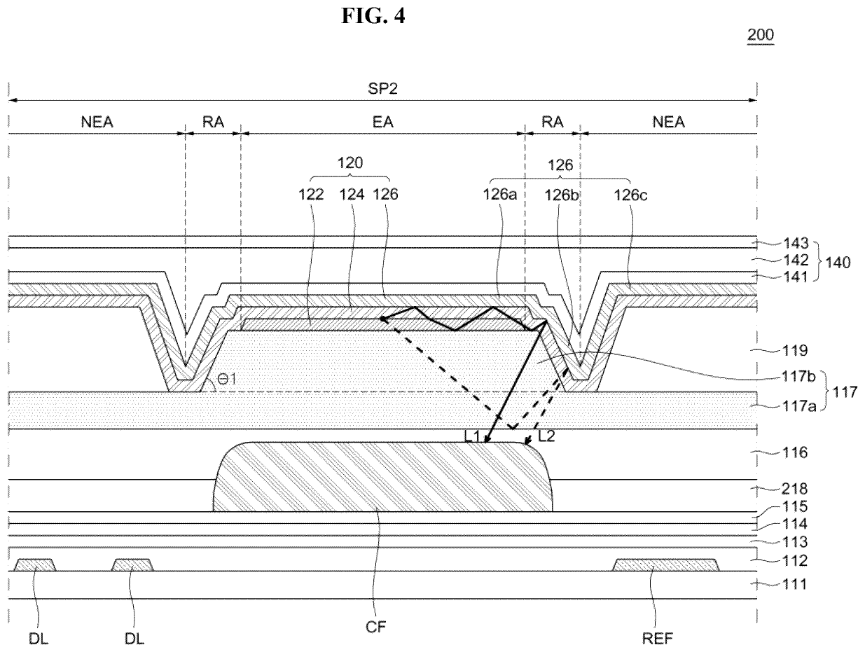

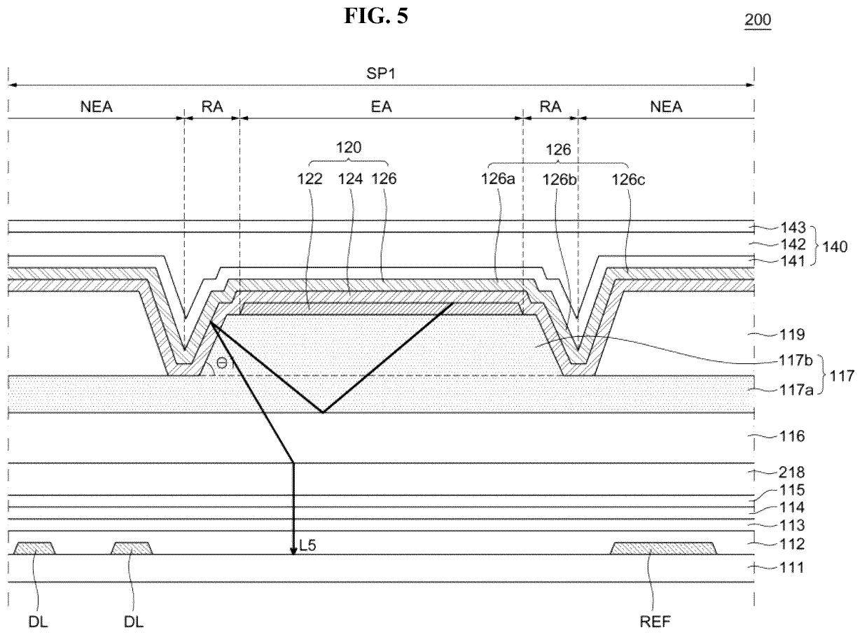

FIGS. 4 and 5 are schematic diagrams for illustrating a display device according to a second embodiment of the present disclosure.

FIG. 4 is a schematic cross-sectional view illustrating a second sub-pixel of the display device 200 according to the second embodiment of the present disclosure. FIG. 5 is a schematic cross-sectional view illustrating a first sub-pixel of the display device 200 according to a second embodiment of the present disclosure. In this case, a plan view showing the pixel structure of the display device 200 of the second embodiment may be the same as the plan view of FIG. 2 showing the pixel structure of the display device 100 of the first embodiment. Accordingly, referring to the plan view of FIG. 2 showing the pixel structure of the display device 100 of the first embodiment, the second sub-pixel of FIG. 4 may be a red sub-pixel, and the first sub-pixel of FIG. 5 may be a white sub-pixel.

A display device 200 according to a second embodiment illustrated in FIGS. 4 and 5 may have the substantially same configurations as the display device 100 according to the first embodiment illustrated in FIGS. 3A and 3B except that an organic buffer layer 218 may be further included, so that a redundant description will be omitted.

Firstly, referring to FIG. 4 illustrating a schematic cross-sectional view of a second sub-pixel which is a red sub-pixel, an organic buffer layer 218 may be disposed between the protective layer 115 and the first overcoating layer 116. In this case, the organic buffer layer 218 may be disposed to cover the protective layer 115. Further, the organic buffer layer 218 may be disposed to expose a part of the source electrode 132 or the drain electrode 133 of the driving thin film transistor 130.

The organic buffer layer 218 may be disposed on the same plane as the color filter CF. In this case, the thickness of the organic buffer layer 218 may be smaller than the thickness of the color filter CF. In this case, the top surface of the color filter CF may be positioned higher than the top surface of the organic buffer layer 218 to be exposed from the organic buffer layer 218. Accordingly, the organic buffer layer 218 may be disposed to be in contact with a part of the side surface of the color filter CF. The thickness of the organic buffer layer 218 may be in the range from about 0.5 μm to about 2.0 μm or in the range of about 0.5 μm to about 1.5 μm or about 1 μm, but is not limited thereto.

A refractive index of the organic buffer layer 218 may be greater than a refractive index of the first overcoating layer 116 and less than a refractive index of the second overcoating layer 117. For example, the refractive index of the organic buffer layer 218 may be in the range from about 1.45 to about 1.60 or in the range from about 1.50 to about 1.60, but is not limited thereto. Since the organic buffer layer 218 has a refractive index larger than that of the first overcoating layer 116 in contact with the upper surface, when light emitted from the light emitting element passes through an interface between the organic buffer layer 218 and the first overcoating layer 116, light may be refracted in the front direction. Accordingly, the front luminance of the display device may be improved.

The organic buffer layer 218 may be formed of an organic material that satisfies the above-described refractive index. For example, the organic buffer layer 218 may be formed of a material having a refractive index of in the range from about 1.40 to about 1.60. For example, the organic buffer layer 218 may be made of one or more materials of acrylic resin, epoxy resin, phenolic resin, polyamides resin, polyimides resin, unsaturated polyesters resin, polyphenylene resin, benzocyclobutene, and polyphenylene sulfide resin, but is not limited thereto.

The first overcoating layer 116 may be disposed on the organic buffer layer 218 and the color filter CF. The first overcoating layer 116 may be disposed to cover the color filter CF protruding from the top surface of the organic buffer layer 218. In particular, the first overcoating layer 116 may be disposed to be in contact with the top surface and the side surface of the protruding color filter CF exposed from the organic buffer layer 218. Accordingly, the first overcoating layer 116 may serve as a planarization layer.

The first overcoating layer 116 may have a low refractive index of about 1.50 or less or about 1.40 or less. As described above in the first embodiment, the first overcoating layer 116 having a low refractive index of about 1.40 or less may be formed of a siloxane-based resin. However, due to the characteristics of the siloxane-based resin, when the first overcoating layer 116 having a refractive index of about 1.40 or less is implemented, it is difficult to make a sufficient thickness of the first overcoating layer 116. For example, a thickness of the first overcoating layer 116 having a refractive index of about 1.40 or less may be about 2.0 μm or less. In this case, the first overcoating layer 116 may not cover the top surface of the color filter CF. Accordingly, the organic buffer layer 218 may be disposed below the first overcoating layer 116 to compensate for the insufficient thickness of the first overcoating layer 116.

Next, referring to FIG. 5 illustrating a schematic cross-sectional view of the first sub-pixel SP1 which is a white sub-pixel, in the case of the white sub-pixel, unlike the second sub-pixel SP2 which is a red sub-pixel, the color filter may not be disposed.

Meanwhile, the light L5 emitted from the organic layer 124 and directed toward the substrate 111 may be re-reflected by the second area 126b of the cathode 126 and then emitted toward the substrate 111 due to a difference in refractive index between the first overcoating layer 116 and the second overcoating layer 117. In this case, the light L5 may be refracted at the interface between the first overcoating layer 116 and the organic buffer layer 218 by a difference in refractive index between the first overcoating layer 116 and the organic buffer layer 218. Accordingly, the organic buffer layer 218 significantly may increase the number of outgoing light directed in the front direction so that the light efficiency is improved.

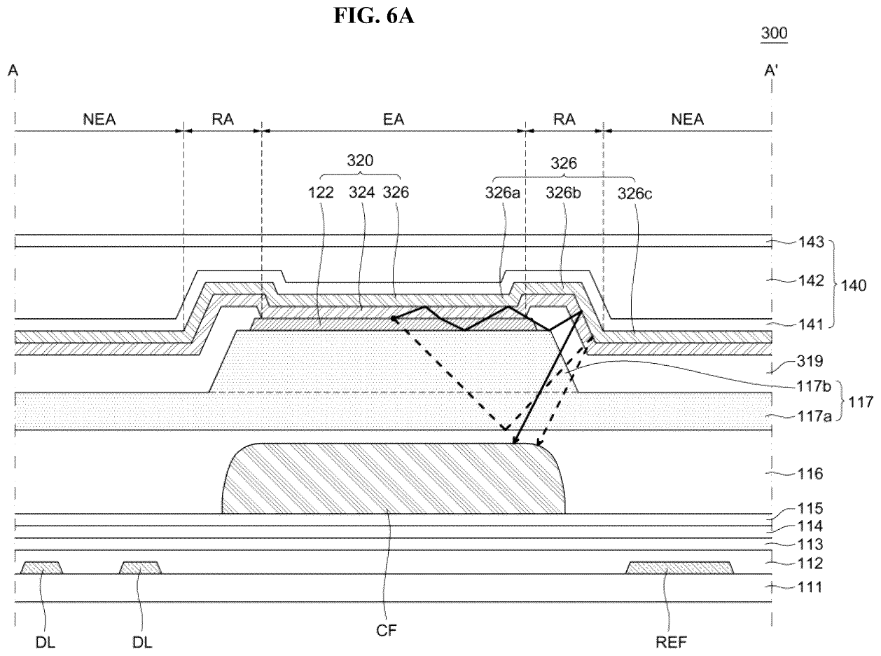

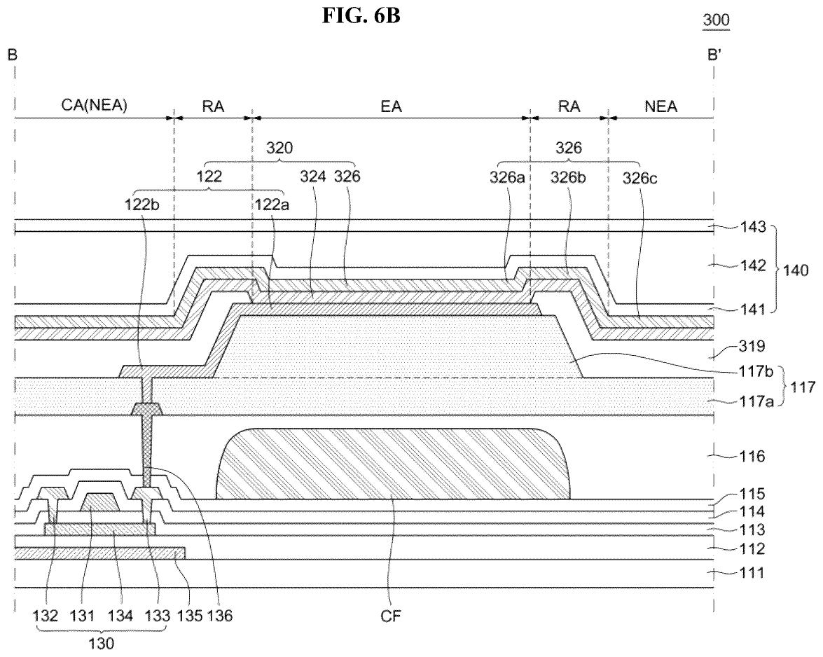

FIGS. 6A and 6B are schematic diagrams for explaining a display device according to a third embodiment of the present disclosure.

FIGS. 6A and 6B are schematic cross-sectional views illustrating one sub-pixel of the display device 300 according to the third embodiment of the present disclosure. In this case, a plan view showing the pixel structure of the display device 300 of the third embodiment may be the same as the plan view of FIG. 2 showing the pixel structure of the display device 100 of the first embodiment. Accordingly, referring to the plan view of FIG. 2 showing the pixel structure of the display device 100 of the first embodiment, FIG. 6A is a schematic cross-sectional view taken along line A-A′ of FIG. 2, and FIG. 6B is a schematic cross-sectional view taken along line B-B′ of FIG. 2.

A display device 300 according to a third embodiment illustrated in FIGS. 6A and 6B has the substantially same configurations as the display device 100 according to the first embodiment illustrated in FIGS. 3A and 3B except that a light emitting element 320 and a bank 319 may be different, so that a redundant description will be omitted.

Referring to FIGS. 6A and 6B, the bank 319 may be disposed on the second overcoating layer 117 in the reflective area RA and the non-emission area NEA. Unlike the bank 119 in the first embodiment shown in FIGS. 3A and 3B which are spaced apart from the emission area EA and are not disposed in the reflection area RA, in the third embodiment, the bank 319 may be disposed in the emission area EA and may be disposed in contact with a part of a top surface and a side surface of the protruding portion 117b of the second overcoating layer 117. The bank 319 may be disposed to cover an edge of the anode 122 disposed on the protruding portion 117b of the second overcoating layer 117 to define the emission area EA. The bank 319 extends from an edge of the anode 122 and may be disposed in the reflective area RA and the non-emission area NEA.

The organic layer 324 may be disposed on the anode 122 in the emission area EA and may be disposed on the bank 319 in the reflection area RA and the non-emission area NEA. Accordingly, in the reflective area RA, the organic layer 324 may be disposed to be spaced apart from the side surface of the protruding portion 117b of the second overcoating layer 117 by the bank 319.

The cathode 326 may be disposed on the organic layer 324 so as to face the anode 122 with the organic layer 324 interposed therebetween. The cathode 326 is not separated for each of the plurality of sub-pixels and may be configured as a common layer.

The cathode 326 may be sequentially disposed on the anode 122 and the organic layer 324 in the emission area EA, and may be disposed on the organic layer 324 in the reflection area RA and the non-emission area NEA. Accordingly, the cathode 326 of the third embodiment of the present disclosure may include a first area 326a which is disposed in the emission area EA and whose surface is substantially parallel to the surface of the substrate 111, a second area 326b which extends from the first area 326a and whose surface has a predetermined angle with respect to the substrate 111, and a third area 326c which extends in a sub-pixel direction adjacent to the second area 326b.

In this case, the second area 326b of the cathode 326 may correspond to the side portion of the protruding portion 117b. Accordingly, the second area 326b of the cathode 326 may be referred to as a side portion of the cathode 326. The second area 326b of the cathode 326 may be disposed on the left and right sides of the emission area EA. In the reflective area RA, a bank 319 may be disposed between the side portion of the protruding portion 117b and the organic layer 324 so that the second area 326b of the cathode 326 is spaced apart from the side portion of the protruding portion 117b. Accordingly, in the third embodiment of the present disclosure, the second area 326b of the cathode 326 may constitute a mirror structure (e.g. a side mirror structure) spaced apart from the side portion of the protruding portion 117b and having a predetermined angle with respect to the substrate 111 by the side portion of the protruding portion 117b. Compared with the first and second embodiments, the mirror structure (e.g. the side mirror structure) formed by the cathode 326 in the third embodiment may be disposed to be spaced apart from the protruding portion 117b. Accordingly, the light path emitted from the light emitting element 320 may be different.

Hereinafter, a simulation result showing light emission according to a light emission angle of the first and second embodiments and a comparative example.

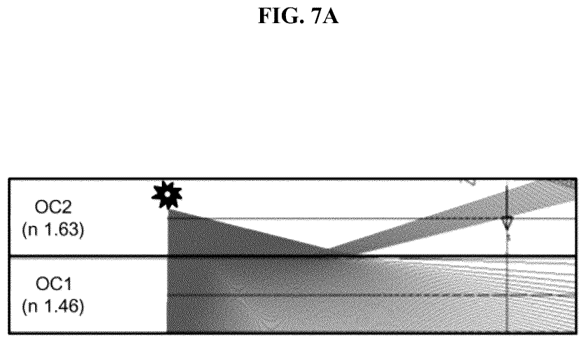

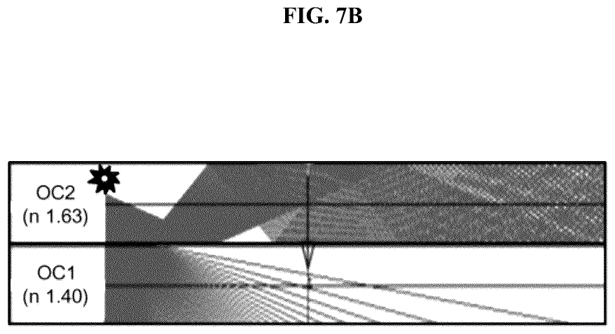

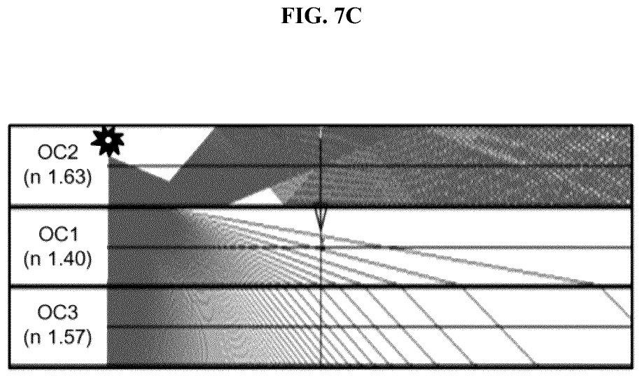

FIG. 7A is a schematic simulation result showing light emission according to a light emission incident angle in a comparative example. FIG. 7B is a schematic simulation result showing light emission according to a light emission incident angle in the first embodiment. FIG. 7C is a schematic simulation result showing light emission according to a light emission incident angle in a second embodiment.

In the comparative example, a first overcoating layer OC1 having a refractive index of about 1.46 and a thickness of about 1.0 μm and a second overcoating layer OC2 having a a refractive index of about 1.63 and a thickness of about 1.5 μm may be sequentially laminated.

In the first embodiment, a first overcoating layer OC1 having a refractive index of about 1.40 and a thickness of about 1.0 μm and a second overcoating layer OC2 having a refractive index of about 1.63 and a thickness of about 1.5 μm may be sequentially laminated.

In the second embodiment, an organic buffer layer (OC3) having a refractive index of about 1.57 and a thickness of about 1.5 μm, a first overcoating layer (OC1) having a refractive index of about 1.40 and a thickness of about 1.0 μm, and a second overcoating layer (OC2) having a refractive index of about 1.63 and a thickness of about 1.5 μm may be sequentially laminated.

Firstly, comparing FIGS. 7A and 7B, in the case of the comparative example, when the refractive index of the first overcoating layer is about 1.46, there may be no reflectance gap, so that total reflection does not occur. However, in the case of the first embodiment, when the refractive index of the first overcoating layer is about 1.40 lower than about 1.46 of the comparative example, the reflectance gap may increase, and total reflection may occur. Accordingly, in the case of the first embodiment, through total reflection by the first overcoating layer, light is guided from the light emitting element to increase the amount of light directed to the reflective area (e.g. the amount of light guided from the light emitting element to the reflective area may increase). Since the amount of light toward the substrate is increased by the light reflected from the reflective area RA, light efficiency and luminance may be improved.

Meanwhile, referring to FIG. 7C, in the second embodiment in which an organic buffer layer having a refractive index of about 1.57 and a thickness of about 1.5 μm is added under the first overcoating layer, not only total reflection may occur between the first overcoating layer and the second overcoating layer, but also light refracted at the interface between the first overcoating layer and the organic buffer layer may be refracted at an angle of about 65 degrees with respect to the boundary surface. As shown in FIG. 7B, in the first embodiment in which the organic buffer layer is not disposed, the light refracted at the interface between the first overcoating layer and the second overcoating layer may be refracted at an angle of about 15 degrees with respect to the boundary surface. Therefore, it may be seen that the second embodiment has a larger amount of light extracted in the vertical direction than the first embodiment. Accordingly, it may be seen that the second embodiment shown in FIG. 7C significantly increases the number of outgoing light directed toward the front surface, thereby improving the light efficiency.

Hereinafter, the light extraction efficiency according to the refractive index of the first overcoating layer and the second overcoating layer is evaluated. The thicknesses of the first overcoating layer and the second overcoating layer according to each example and comparative example are about 1.5 μm, respectively, and refractive indices of the first overcoating layer and the second overcoating layer are described in Table 1 below. For the first Example, the second Example, and the third Example according to the embodiments of the present disclosure, the first Comparative Example, and the second Comparative Example, white light efficiency and front extraction rate were measured using light tools. The measurement results are shown in Table 1.

TABLE 1

| | Refractive | Refractive | | |
|---|---|---|---|---|
| | index of | index of | White | Front |
| | the first | the second | light | extraction |
| | overcoating | overcoating | efficiency | rate |
| | layer | layer | (cd/A) | (%) |
| First Example | 1.40. | 1.63 | 149.15 | 21 |
| Second Example | 1.43 | 1.68 | 148.67 | 18 |
| Third Example | 1.46 | 1.70 | 149.39 | 18 |
| First Comparative | 1.46 | 1.63 | 137.72 | 15 |
| Example | | | | |
| Second Comparative | 1.57 | 1.57 | 124.42 | 4 |
| Example | | | | |

Referring to Table 1, it may be confirmed that the luminous efficiency and the frontal extraction rate of the first, second, and third Examples are significantly improved compared to the second comparative example in which the refractive indices of the first overcoating layer and the second overcoating layer were the same. In addition, referring to the first comparative example, when the difference in refractive index between the first overcoating layer and the second overcoating layer is about 0.2 or more, the luminous efficiency and the frontal extraction rate may be further improved. Furthermore, it may be confirmed that the refractive index of the first overcoating layer is about 1.40, and in the case of the first Example, which is an ultra-low refractive index, the luminous efficiency and the frontal extraction rate may be better than those of the second and third Examples.

A display device according to one embodiment of the present disclosure may include a substrate having a plurality of sub-pixels, a first overcoating layer disposed on the substrate, a second overcoating layer including a bottom surface layer disposed on the first overcoating layer and a protruding portion protruding at least partially from the bottom surface layer, an anode disposed on a top surface of the protruding portion of the second overcoating layer, an organic layer disposed on the anode, and a cathode disposed on the organic layer corresponding to the top surface and a side surface of the protruding portion, and a refractive index of the first overcoating layer may be smaller than a refractive index of the second overcoating layer.

The refractive index of the first overcoating layer may be in the range from about 1.30 to about 1.45.

The difference between the refractive index of the first overcoating layer and the refractive index of the second overcoating layer may be about 0.2 or more.

The first overcoating layer may include a siloxane-based resin.

The protruding portion may have a shape protruding corresponding to an emission area of the sub-pixel.

The display device may further include a bank disposed on a part of the top surface of the second overcoating layer excluding the protruding portion and spaced apart from the protruding portion.

The organic layer may extend to be in contact with the side surface of the protruding portion, and the cathode may include a first area positioned on the top surface of the protruding portion, and a second area extending from the first area and disposed on the organic layer corresponding to the side surface of the protruding portion.

The display device may further include a bank disposed on a part of the top surface of the protruding portion, the side surface of the protruding portion, and a part of a top surface of the second overcoating layer excluding the protruding portion to cover an edge of the anode, and the thickness of the bank may be smaller than the thickness of the protruding portion.

The organic layer may be disposed on the bank corresponding to the side surface of the protruding portion, the cathode may include a first area positioned on the top surface of the protruding portion, and a second area extended from the first area and disposed on the organic layer corresponding to the side surface of the protruding portion, and the second area of the cathode may be spaced apart from the side surface of the protruding portion.

The display device may further include a plurality of color filters respectively disposed on the substrate corresponding to an emission area of each of the plurality of sub-pixels, and the thickness of each of the plurality of color filters may be smaller than the thickness of the first overcoating layer.

The display device may further include an organic buffer layer disposed below the first overcoating layer, and a refractive index of the organic buffer layer may be greater than that of the first overcoating layer and less than a refractive index of the second overcoating layer.

The refractive index of the organic buffer layer may be in the range from about 1.45 to about 1.60, the refractive index of the first overcoating layer may be in the range from about 1.30 to about 1.45, and the refractive index of the second overcoating layer may be in the range from about 1.60 to about 1.70.

The display device may further include a plurality of color filters respectively disposed on the substrate corresponding to an emission area of each of the plurality of sub-pixels, each of the plurality of color filters may be disposed on the same layer as the organic buffer layer and surrounded by the organic buffer layer, and a thickness of each of the plurality of color filters may be greater than a thickness of the organic buffer layer, and the first overcoating layer may cover top surfaces and side surfaces of the plurality of color filters exposed by the organic buffer layer.

The thickness of the organic buffer layer may be in the range from about about 0.5 μm to about 1.0 μm, and the thickness of the first overcoating layer may be in the range from about about 1.0 μm to about 2.5 μm.

The display device may further comprise a thin film transistor disposed on the substrate and a light shielding layer disposed between the substrate and the thin film transistor, wherein the light shielding layer may not overlap the side surface of the protruding portion.

In addition, it is possible to contribute to eco-friendliness by replacing a fluorine-containing material, which is a harmful material conventionally used as an overcoating layer, thereby implementing environment/social/governance (ESG).

According to one embodiment of the present disclosure, a display device with improved light extraction efficiency may be provided by including a side mirror structure of a cathode.

According to one embodiment of the present disclosure, a display device in which a total reflection effect due to a difference in refractive index is increased by applying a plurality of overcoating layers including an ultra-low refractive layer, thereby improving light extraction efficiency by a side mirror may be provided.

According to one embodiment of the present disclosure, by applying a triple overcoating layer having a different refractive index, it is possible to provide a display device in which front light extraction efficiency and front light luminance are improved by increasing the amount of outgoing light toward the front direction.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A display device, comprising:
a substrate including a plurality of sub-pixels;
a first overcoating layer disposed on the substrate;
a second overcoating layer including a bottom surface layer disposed on the first overcoating layer and a protruding portion protruded at least partially from the bottom surface layer;
an anode disposed on a top surface of the protruding portion of the second overcoating layer;
an organic layer disposed on the anode; and
a cathode disposed on the organic layer corresponding to the top surface and a side surface of the protruding portion,
wherein a refractive index of the first overcoating layer is smaller than a refractive index of the second overcoating layer.

2. The display device of claim 1, wherein the refractive index of the first overcoating layer is in a range from about 1.30 to about 1.45.

3. The display device of claim 2, wherein a difference between the refractive index of the first overcoating layer and the refractive index of the second overcoating layer is about 0.2 or more.

4. The display device of claim 3, wherein the first overcoating layer includes a siloxane-based resin.

5. The display device of claim 1, wherein the protruding portion includes a shape protruded corresponding to an emission area of the sub-pixel.

6. The display device of claim 5, further comprising a bank disposed on a part of a top surface of the second overcoating layer spaced apart from the protruding portion.

7. The display device of claim 6, wherein the organic layer extends to be in contact with the side surface of the protruding portion, and
wherein the cathode includes a first area disposed on the top surface of the protruding portion, and a second area extending from the first area and disposed on the organic layer corresponding to the side surface of the protruding portion.

8. The display device of claim 5, further comprising a bank disposed on a part of the top surface of the protruding portion, the side surface of the protruding portion, and a part of a top surface of the second overcoating layer to cover an edge of the anode,
wherein a thickness of the bank is smaller than a thickness of the protruding portion.

9. The display device of claim 8, wherein the organic layer is disposed on the bank corresponding to the side surface of the protruding portion, and
wherein the cathode includes a first area disposed on the top surface of the protruding portion, and a second area extending from the first area, disposed on the organic layer corresponding to the side surface of the protruding portion, and spaced apart from the side surface of the protruding portion.

10. The display device of claim 1, further comprising a plurality of color filters respectively disposed on the substrate corresponding to an emission area of each of the plurality of sub-pixels,
wherein a thickness of each of the plurality of color filters is smaller than a thickness of the first overcoating layer.

11. The display device of claim 1, further comprising an organic buffer layer disposed below the first overcoating layer,
wherein a refractive index of the organic buffer layer is greater than a refractive index of the first overcoating layer and less than a refractive index of the second overcoating layer.

12. The display device of claim 11, wherein:
the refractive index of the organic buffer layer is in a range from about 1.45 to about 1.60;
the refractive index of the first overcoating layer is in a range from about 1.30 to about 1.45; and
the refractive index of the second overcoating layer is in a range from about 1.60 to about 1.70.

13. The display device of claim 11, further comprising a plurality of color filters respectively disposed on the substrate corresponding to an emission area of each of the plurality of sub-pixels,
wherein each of the plurality of color filters is disposed on a same layer as the organic buffer layer and is surrounded by the organic buffer layer,
a thickness of each of the plurality of color filters is larger than a thickness of the organic buffer layer, and
the first overcoating layer covers the top and side surfaces of each of the plurality of color filters exposed by the organic buffer layer.

14. The display device of claim 13, wherein the thickness of the organic buffer layer is in a range from about 0.5 μm to about 1.0 μm, and
the thickness of the first overcoating layer is in a range from about 1.0 μm to about 2.5 μm.

15. The display device of claim 1, further comprising:
a thin film transistor disposed on the substrate; and
a light shielding layer disposed between the substrate and the thin film transistor,
wherein the light shielding layer does not overlap the side surface of the protruding portion.
